(19) United States
(12) Patent Application Publication
(10) Pub. No.: US 2006/0160273 A1
(43) Pub. Date: Jul. 20, 2006

(54) METHOD FOR WAFER LEVEL PACKAGING

(76) Inventor: Chih-Hsien Chen, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 10/906,935

(22) Filed: Mar. 14, 2005

(30) Foreign Application Priority Data
Jan. 19, 2005 (TW) 094101548

(51) Int. Cl. H01L 21/46

(52) U.S. Cl. 438/113; 438/455; 438/458

(57) ABSTRACT

A device wafer including a plurality of devices and a plurality of contact pads positioned on a top surface of the device wafer and electrically connected to the devices is provided. Subsequently, a cap wafer is provided. Following that, a plurality of bonding patterns and a plurality of cavity patterns are formed on a bottom surface of the cap wafer. Thereafter, the top surface of the device wafer and the bottom surface of the cap wafer are bonded together with the bonding patterns, wherein the cavity patterns are aligned to the contact pads.

### BACKGROUND OF INVENTION

1. Field of the Invention

The present invention relates to a method for wafer level packaging, and more particularly, to a method for wafer level packaging that locally bonds a device wafer and a cap wafer with bonding patterns.

2. Description of the Prior Art

A package process is a most crucial step in back-end processes of semiconductor or MEMS (micro-electromechanical system) manufacture. The yield of the package process not only dominates the performance of semiconductor device products or the MEMS device products, but also is the key to chip miniaturization. Please refer to FIG. 1 through FIG. 4. FIG. 1 through FIG. 4 are schematic diagrams illustrating a conventional package method. As shown in FIG. 1, a device wafer 10 to be packaged is provided. The device wafer 10 includes a plurality of devices 12, and a plurality of contact pads 14 disposed on the surface of the device wafer 10. Subsequently, a segmenting process is performed according to predefined scribe lines (not shown) so as to divide the device wafer 10 into a plurality of dies 16.

As shown in FIG. 2, a cap wafer 18 is provided. The cap wafer 18 is segmented into a plurality of caps 20, the shape of each cap 20 corresponds to each die 16, and the size of each cap 20 is slightly smaller than the die 16. As shown in FIG. 3, a bonding layer 22 is disposed on the surface of the die 16, wherein the bonding layer 22 does not cover the contact pad 14. Finally as shown in FIG. 4, each cap 20 and each die 16 are bonded together with the bonding layer 22.

The conventional package method suffers the following drawbacks. In the first place, the device wafer is divided into the dies before packaging, and therefore the conventional package process has to be performed manually. This results in low efficiency and poor yield. In addition, the conventional package method has high manufacture costs, and cannot meet the requirements of device miniaturization.

### SUMMARY OF INVENTION

It is therefore a primary object of the claimed invention to provide a method for wafer level packaging to overcome the aforementioned problem.

According to the claimed invention, a method for wafer level packaging is disclosed. First, a device wafer including a plurality of devices and a plurality of contact pads positioned on a top surface of the device wafer and electrically connected to the devices is provided. Subsequently, a cap wafer is provided. Following that, a plurality of bonding patterns and a plurality of cavity patterns are formed on a bottom surface of the cap wafer. Thereafter, the top surface of the device wafer and the bottom surface of the cap wafer are bonded together with the bonding patterns, wherein the cavity patterns are aligned to the contact pads.

The method for wafer level packaging locally bonds a cap wafer to a device wafer, and thus the devices formed in the device wafer are well protected. By virtue of the arrangements of the bonding patterns and the cavity patterns, the cap wafer positioned corresponding to the peripheral regions can be easily removed without damaging the contact pads. Accordingly, further packaging procedures can be easily carried out.

These and other objectives of the present invention will no doubt become obvious to those of ordinary skill in the art after having read the following detailed description of the preferred embodiment that is illustrated in the various figures and drawings.

### BRIEF DESCRIPTION OF DRAWINGS

FIG. 1 through FIG. 4 are schematic diagrams illustrating a conventional packaging method.

FIG. 5 through FIG. 10 are schematic diagrams illustrating a method for wafer level packaging according to a preferred embodiment of the present invention.

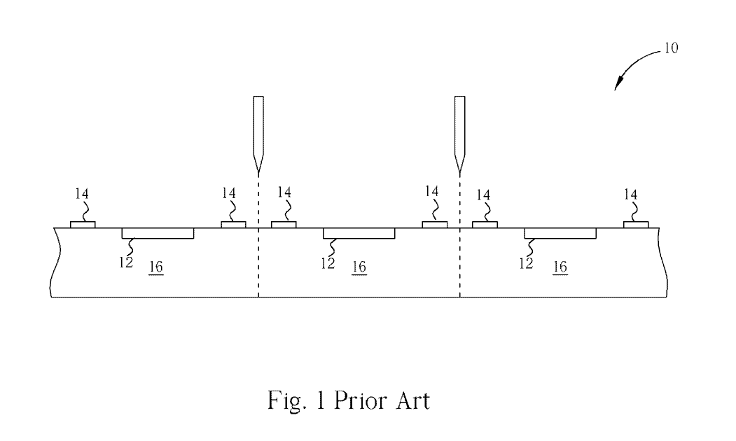

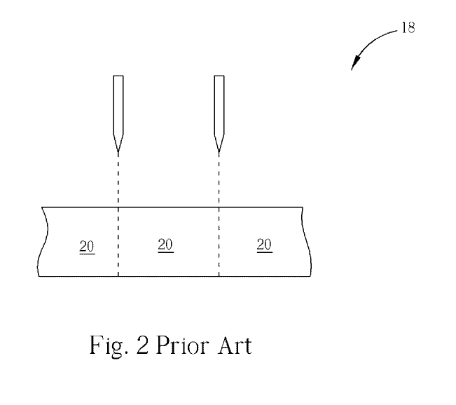

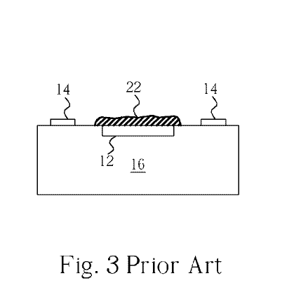

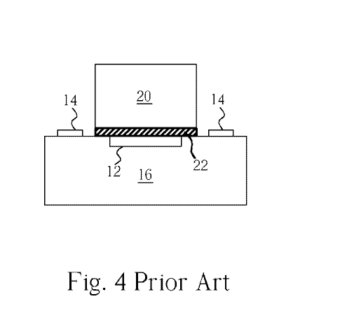

### DETAILED DESCRIPTION

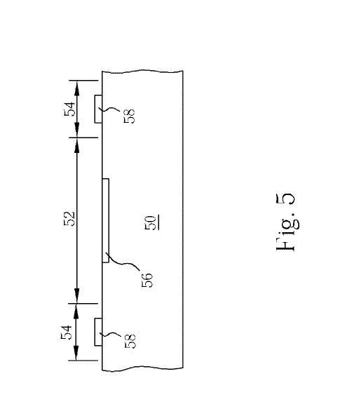

Please refer to FIG. 5 through FIG. 10. FIG. 5 through FIG. 10 are schematic diagrams illustrating a method for wafer level package according to a preferred embodiment of the present invention. For highlighting the features of the present invention and clear illustration, FIG. 5 through FIG. 10 only show a device region and a peripheral region. As shown in FIG. 5, a device wafer 50 is provided. The device wafer 50 is divided into a plurality of device regions 52 and a plurality of peripheral regions 54. The device wafer 50 includes a plurality of devices 56 positioned in the device regions 52, and a plurality of contact pads 58, which are exposed on the top surface of the device wafer 50, disposed in the peripheral regions 54. The device wafer 50 can be a semiconductor wafer, e.g. a silicon wafer, or other wafers for fabricating various devices. The devices 56 can be any semiconductor devices, photosensitive devices, or MEMS devices. The devices 56 and the contact pads 58 are electrically connected to one another with a plurality of interconnections (not shown).

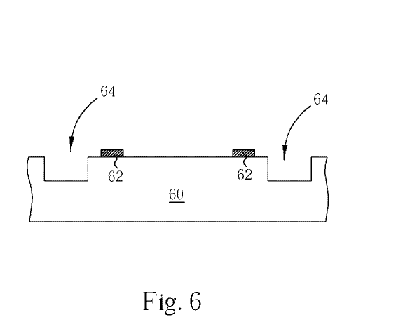

As shown in FIG. 6, a cap wafer 60 is provided. Then, a plurality of bonding patterns 62 and a plurality of cavity patterns 64 are formed on the bottom surface of the cap wafer 60. The bonding patterns 62 correspond to peripheral areas of the device regions 52. The cavity patterns 64 correspond to the contact pads 58. Regarding different requirements, the cap wafer 60 can be made of different materials. For instance, if the devices 56 are photosensitive devices, a glass wafer or a quartz wafer is selected. If the devices 56 are semiconductor devices or MEMS devices, a semiconductor wafer is preferred. The material of the bonding patterns 62 can be metal, e.g. solder or gold, or non-metal, e.g. polyimide or epoxy. In addition, the bonding patterns 62 can be formed by different techniques where necessary. For example, if the bonding patterns 62 are made of metal material, an evaporation deposition technique, sputtering, deposition technique, electroplating technique, or halftone technique can be adopted. If the bonding patterns 62 are made of non-metal material, a halftone technique or coating technique can be utilized. The cavity patterns 64 can be formed by laser cutting, mechanical cutting, or etching techniques basing on the material characteristics of the cap wafer 60. In addition, the sequences of forming the bonding patterns 62 and the cavity patterns 64 can be swapped where necessary.

Additionally, alignment keys (not shown) are formed on the surface of the cap wafer 60 before bonding the device wafer 50 and the cap wafer 60 for ensuring accurate alignment. It is noted that particles tend to appear together with the process of forming the alignment keys or the cavity patterns 64, and thus a cleaning process is performed after forming the cavity patterns 64 for preventing damage to the bonding patterns 62.

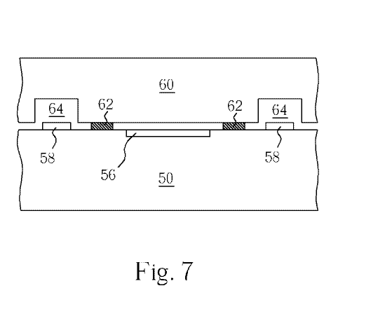

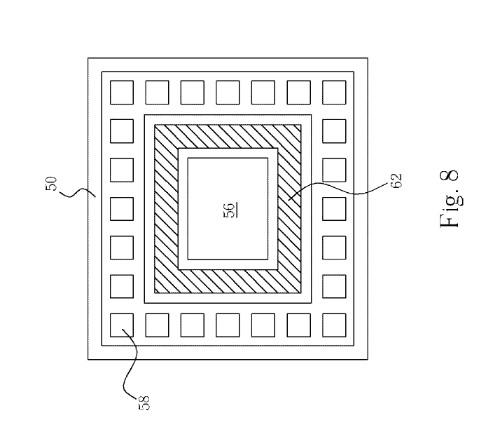

Please refer to FIG. 7 and FIG. 8. As shown in FIG. 7, an aligning process is performed utilizing the alignment keys (not shown) predefined on the surface of the cap wafer 60 to align the cap wafer 60 and the device wafer 50. Subsequently, the top surface of the device wafer 50 and the bottom surface of the cap wafer 60 are bonded together with the bonding patterns 62. Accordingly, the devices 56 are hermetically (i.e. airtight) sealed in by the cap wafer 60, the device wafer 50, and the bonding patterns 62. The airtight structure prevents the devices 56 from being damaged in successive processes. As shown in FIG. 8, each bonding pattern 62 is a closed pattern surrounding each device 56, and thus is able to effectively protect the device 56. In addition, each cavity pattern 64 is generally a circular pattern, so that a buffer space forms above the contact pads 58 for the convenience of the following segmenting process.

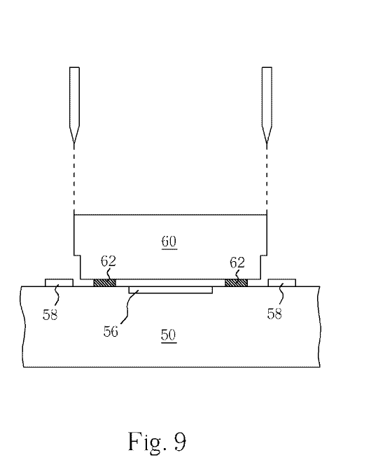

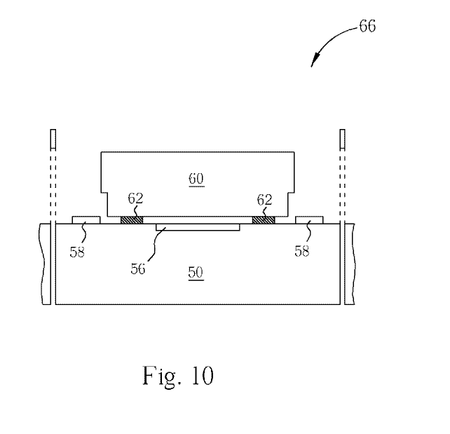

Please refer to FIG. 9. As shown in FIG. 9, the cap wafer 60 is segmented from the top surface at positions corresponding to the cavity patterns 64 until the cap wafer 60 is cut through. Then, a cleaning process is performed to remove particles generated when segmenting the cap wafer 60. The cap wafer 60 can be segmented by laser cutting, mechanical cutting, or etching techniques. As shown in FIG. 10, the device wafer 50 is segmented based on predefined scribe lines (not shown) so as to form a plurality of dies 66. The device wafer 50 can be segmented by laser cutting, mechanical cutting, or etching techniques, from the top surface of the bottom surface of the device wafer 50.

The method for wafer level packaging of the present invention locally bonds a cap wafer to a device wafer, and thus the devices formed on the device wafer are well protected. By virtue of the arrangements of the bonding patterns and the cavity patterns, the cap wafer positioned corresponding to the peripheral regions can be easily removed without damaging the contact pads. Accordingly, further packaging procedure can be easily carried out. In comparison with the prior art, the method of the present invention is a batch-type procedure, and thus has a higher yield and a lower manufacturing cost.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method for wafer level packaging comprising:
providing a device wafer, the device wafer comprising a plurality of devices, and providing a plurality of contact pads positioned on a top surface of the device wafer and electrically connected to the devices;
providing a cap wafer;
forming a plurality of bonding patterns and a plurality of cavity patterns on a bottom surface of the cap wafer; and
bonding the top surface of the device wafer and the bottom surface of the cap wafer with the bonding patterns, wherein the cavity patterns are aligned to the contact pads.

2. The method of claim 1, wherein the devices are photosensitive devices.

3. The method of claim 1, wherein the devices are semiconductor devices.

4. The method of claim 1, wherein the devices are MEMS (micro-electromechanical system) devices.

5. The method of claim 1, wherein the cap wafer is selected from a group consisting of semiconductor wafers, glass wafers, and quartz wafers.

6. The method of claim 1, wherein each bonding pattern is a closed pattern formed corresponding to a peripheral area of each device.

7. The method of claim 1, wherein the material of the bonding patterns is metal.

8. The method of claim 1, wherein the material of the bonding patterns is non-metal.

9. The method of claim 1, wherein the bonding patterns are formed on the bottom surface of the cap wafer prior to forming the cavity patterns.

10. The method of claim 1, wherein the cavity patterns are formed on the bottom surface of the cap wafer prior to forming the bonding patterns.

11. The method of claim 1, subsequent to bonding the device wafer and the cap wafer, further comprising steps of:
segmenting the cap wafer from a top surface of the cap wafer at positions corresponding to the cavity patterns until the cap wafer is cut through;
performing a cleaning process; and
segmenting the device wafer to form a plurality of dies.

12. A method for wafer level packaging comprising:
providing a device wafer, the device wafer comprising a plurality of device regions and a plurality of peripheral regions, the device wafer further comprising a plurality of devices positioned in the device regions and a plurality of contact pads exposed on a top surface of the device wafer and positioned in the peripheral regions;
providing a cap wafer;
forming a plurality of bonding patterns and a plurality of cavity patterns on a bottom surface of the cap wafer, each bonding pattern corresponding to a peripheral area of each device region, and each cavity pattern corresponding to a portion of the contact pads;
bonding the top surface of the device wafer and the bottom surface of the cap wafer with the bonding patterns, the devices being hermetically sealed between the device wafer and the cap wafer, and the cavity patterns being aligned to the contact pads;
segmenting the cap wafer from a top surface of the cap wafer at positions corresponding to the cavity patterns until the cap wafer is cut through;
performing a cleaning process; and
segmenting the device wafer to form a plurality of dies.

13. The method of claim 12, wherein the devices are photosensitive devices.

14. The method of claim 12, wherein the devices are semiconductor devices.

15. The method of claim 12, wherein the devices are MEMS (micro-electromechanical system) devices.

16. The method of claim 12, wherein the cap wafer is selected from a group consisting of semiconductor wafers, glass wafers, and quartz wafers.

17. The method of claim 12, wherein the material of the bonding patterns is metal.

18. The method of claim 12, wherein the material of the bonding patterns is non-metal.

19. The method of claim 12, wherein the bonding patterns are formed on the bottom surface of the cap wafer prior to forming the cavity patterns.

20. The method of claim 12, wherein the cavity patterns are formed on the bottom surface of the cap wafer prior to forming the bonding patterns.
